(19) United States
(12) Patent Application Publication
(10) Pub. No.: US 2024/0357893 A1
(43) Pub. Date: Oct. 24, 2024

(54) DISPLAY PANEL AND DISPLAY TERMINAL

(71) Applicant: HKC CORPORATION LIMITED, Shenzhen (CN)

(72) Inventors: Qin LIANG, Shenzhen (CN); Zhi YANG, Shenzhen (CN); Yangling TANG, Shenzhen (CN); Xiufeng ZHOU, Shenzhen (CN); Baohong KANG, Shenzhen (CN)

(21) Appl. No.: 18/511,210

(22) Filed: Nov. 16, 2023

(30) Foreign Application Priority Data
Apr. 20, 2023 (CN) 202310458506.6

(51) Int. Cl. H10K 59/131; H10K 59/122; H10K 59/80

(52) U.S. Cl. CPC H10K 59/1315; H10K 59/122; H10K 59/8052

(57) ABSTRACT

Provided are a display panel and a display terminal. The display panel includes a display region and a non-display region surrounding the display region. The display panel includes a cathode signal trace and a cathode layer, the cathode signal trace includes a first trace part, and the first trace part is located in the display region, the cathode layer is located at one side of the cathode signal trace, covers the display region, and is electrically connected to the first trace part.

### CROSS-REFERENCE TO RELATED APPLICATIONS

This application claims priority under 35 U.S.C. § 119 (a) to Chinese Patent Application No. 2023104585066, filed Apr. 20, 2023, the entire disclosure of which is incorporated herein by reference.

### TECHNICAL FIELD

The disclosure relates to the field of display technology, and in particular, to a display panel and a display terminal.

### BACKGROUND

An organic light emitting diode (OLED) display panel is widely used in display terminals such as mobile phones, computers, and televisions because of its advantages of active light emission, low voltage driving, and high brightness. In an existing OLED display panel, an ELVSS signal is usually transmitted to an OLED device cathode in a display region through a frame signal trace, however, a contact region needs to be disposed between the frame signal trace and the OLED device cathode in the display region to achieve a punching connection, and the contact region occupies a non-display region of the display panel, which leads to a relatively wide non-display region of the display panel, and the screen-to-body ratio of the display panel is relatively low.

### SUMMARY

In a first aspect, the disclosure provides a display panel. The display panel has a display region and a non-display region surrounding the display region. The display panel includes a cathode signal trace and a cathode layer, the cathode signal trace includes a first trace part, and the first trace part is located in the display region. The cathode layer is located at one side of the cathode signal trace, covers the display region, and is electrically connected to the first trace part.

In a second aspect, the disclosure further provides a display terminal. The terminal includes a housing and the display panel of any one of embodiments above, where the display panel is mounted on the housing.

### BRIEF DESCRIPTION OF THE DRAWINGS

In order to describe technical solutions in embodiments of the disclosure more clearly, the following will give an introduction to the accompanying drawings required for describing embodiments of the disclosure.

FIG. 1 is a schematic planar structural diagram of a display panel according to an embodiment of the disclosure.

FIG. 2 is a schematic cross-sectional structural diagram of the display panel illustrated in FIG. 1 taken along line I-I in the first embodiment.

FIG. 3 is a schematic cross-sectional structural diagram of the display panel illustrated in FIG. 1 taken along line I-I in the second embodiment.

FIG. 4 is a schematic cross-sectional structural diagram of the display panel illustrated in FIG. 1 taken along line I-I in the third embodiment.

FIG. 5 is a schematic cross-sectional structural diagram of the display panel illustrated in FIG. 1 taken along line I-I in the fourth embodiment.

FIG. 6 is a schematic cross-sectional structural diagram of the display panel illustrated in FIG. 1 taken along line I-I in the fifth embodiment.

FIG. 7 is a schematic cross-sectional structural diagram of the display panel illustrated in FIG. 1 taken along line I-I in the sixth embodiment.

FIG. 8 is a schematic cross-sectional structural diagram of the display panel illustrated in FIG. 1 taken along line I-I in the seventh embodiment.

FIG. 9 is a schematic cross-sectional structural diagram of the display panel illustrated in FIG. 1 taken along line I-I in the eighth embodiment.

### DETAILED DESCRIPTION

The following will clearly and completely illustrate technical solutions of embodiments of the present disclosure with reference to accompanying drawings of embodiments of the present disclosure.

Reference is made to FIG. 1, which is a schematic planar structural diagram of a display panel 100 according to an embodiment of the disclosure. It should be noted that, FIG. 1 schematically illustrates a cathode signal trace 110 and a cathode layer 120.

In the embodiment, the display panel 100 is an OLED display panel. The display panel 100 has a display region 101 and a non-display region 102 surrounding the display region 101. The display panel 100 includes a cathode signal trace 110 and a cathode (CAT) layer 120. The cathode signal trace 110 is used for ELVSS signal transmission. In the embodiment, the cathode signal trace 110 includes a first trace part 112, and the first trace part 112 is located in the display region 101. The first trace part 112 is implemented as multiple first trace parts 1. Among the multiple first trace parts 112, part of the first trace parts 112 are arranged at intervals in a first direction X and each extend in a second direction Y, and another part of the first trace parts 112 are arranged at intervals in the second direction Y and each extend in the first direction X. In other words, the multiple first trace parts 112 are arranged in a grid in the display region 101. The first direction X and the second direction Y are perpendicular to each other. Exemplarily, the first direction X is horizontal, and the second direction Y is longitudinal. The cathode layer 120 is located at one side of the cathode signal trace 110, covers the display region 101, and is electrically connected to the multiple first trace parts 112.

In the embodiment, the multiple first trace parts 112 form a grid in the display region 101, and can provide a path for inputting an ELVSS signal to the cathode layer 120 from the entire display region 101, therefore, a contact region electrically connected to the cathode layer 120 does not need to be disposed in the non-display region 102, and the width of the non-display region 102 can be reduced, which helps to reduce a frame of the display panel 100 and improve a screen-to-body ratio. Furthermore, since the ELVSS signal is input into the cathode layer 120 from the whole display region 101, and the cathode layer 120 does not need to be used to transmit the ELVSS signal from an edge of the display region 101 to a middle of the display region 101, a trace voltage drop of the ELVSS signal is reduced, which helps to improve the display uniformity of the display region 101, and the trace resistance of the cathode layer 120 and the power consumption of the display panel 100 are also reduced.

In addition, the cathode signal trace 110 further includes a second trace part 111, and the second trace part 111 is located in the non-display region 102, surrounds the display region 101, and is electrically connected to multiple first trace parts 112 and the cathode layer 120. It should be understood that, in some other embodiments, the cathode signal trace 110 may not include the second trace part 111, and the width of the non-display region 102 of the display panel 100 may be further reduced by cancelling the second trace part 111 located in the non-display region 102, thereby further reducing the frame of the display panel 100 and improving the screen-to-body ratio.

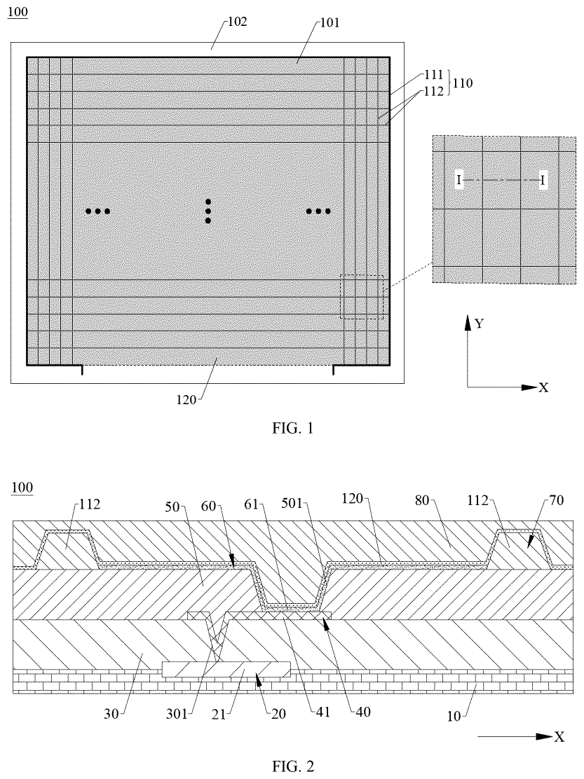

Please also refer to FIG. 2, FIG. 2 is a schematic cross-sectional structural diagram of the display panel 100 illustrated in FIG. 1 taken along line I-I in the first embodiment. The section taken along line I-I refers to a section taken along a plane where the line I-I is located.

In the present embodiment, the display panel 100 includes a base substrate 10, a pixel circuit layer 20, a planarization layer 30, an anode layer 40, a pixel definition layer 50, a light emitting layer 60, a signal transmitting layer 70, and an encapsulation layer 80. The base substrate 10, the pixel circuit layer 20, the planarization layer 30, the anode layer 40, the pixel definition layer 50, the light emitting layer 60, and the signal transmitting layer 70 are all located at the same side of the cathode layer 120, and the encapsulation layer 80 is located at the other side of the cathode layer 120.

The base substrate 10 may be a rigid substrate or a flexible substrate. The rigid substrate may be made of glass, and the flexible substrate may be made of a polymer material such as polyimide. The pixel circuit layer 20 is disposed on a surface of the base substrate 10. The pixel circuit layer 20 may include multiple thin film transistors (TFTs) 21, and the multiple TFTs 21 may be arranged in an array. The planarization layer 30 covers the pixel circuit layer 20 and a surface of the base substrate 10 facing the pixel definition layer 50. The planarization layer 30 defines multiple first through holes 301, and each of the first through holes 301 extends through the planarization layer 30 in a thickness direction of the planarization layer 30 and exposes the pixel circuit layer 20. The multiple first through holes 301 may be arranged in a matrix, and each first through hole 301 exposes one TFT 21.

The anode layer 40 is disposed on a surface of the planarization layer 30 away from the pixel circuit layer 20. The anode layer 40 may be made of a conductive metal oxide such as indium tin oxide. Specifically, the anode layer 40 includes multiple anodes 41, and the multiple anodes 41 may be arranged in an array. Each anode 41 is electrically connected to the pixel circuit layer 20 via one first through hole 301. Exemplarily, each anode 41 is electrically connected to one TFT 21 via one first through hole 301.

The pixel definition layer 50 is disposed on one side of the anode layer 40 facing towards the cathode layer 120. The pixel definition layer 50 defines multiple pixel apertures 501, and each of the pixel apertures 501 extends through the pixel definition layer 50 in a thickness direction of the pixel definition layer 50 and exposes one of the multiple anode 41. The light emitting layer 60 is disposed on the multiple pixel apertures 501 and can emit light under the drive of the pixel circuit layer 20. The light emitting layer 60 includes multiple display pixels 61, and each of the display pixels 61 is disposed on one pixel aperture 501.

The signal transmitting layer 70 is disposed on a surface of the pixel definition layer 50 away from the anode layer 40. The signal transmitting layer 70 includes the multiple first trace parts 112. Two adjacent first trace parts 112 are respectively located at two opposite sides of one pixel aperture 501 in the first direction X, and are both spaced apart from said one pixel aperture 501. That is, two adjacent first trace parts 112 are respectively located at two opposite sides of one anode 41 in the first direction X, and are spaced apart from the anode 41. The signal transmitting layer 70 may be made of low-resistivity metal materials such as silver (Ag) or copper (Cu).

The cathode layer 120 covers the pixel definition layer 50, the light emitting layer 60, and the signal transmitting layer 70, and is electrically connected with the multiple first trace parts 112. The cathode layer 120 may be made of metal materials such as aluminum (Al), gold (Au), silver, etc. The encapsulation layer 80 covers a surface of the cathode layer 120 away from the pixel definition layer 50 for encapsulation and to prevent impurities such as moisture in the external environment from entering the display panel 100.

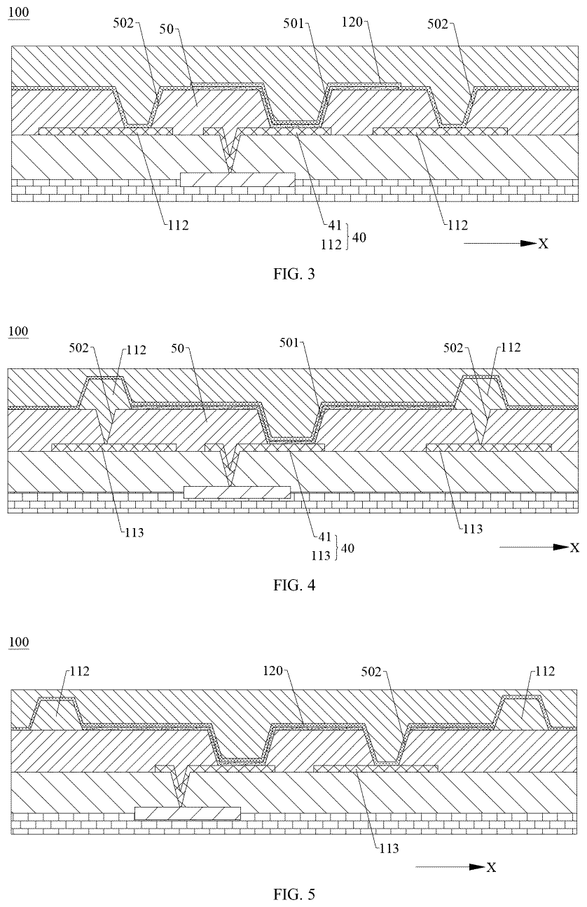

Reference is made to FIG. 3, which is a schematic cross-sectional structural diagram of the display panel 100 illustrated in FIG. 1 taken along line I-I in the second embodiment.

The difference between the display panel 100 of the present embodiment and the display panel 100 of the first embodiment lies in that, an anode layer 40 includes multiple first trace parts 112, and two adjacent first trace parts 112 are located at two opposite sides of one anode 41 in the first direction X and are spaced apart from the anode 41. A pixel definition layer 50 further defines multiple first contact holes 502, and each of the first contact holes 502 extends through the pixel definition layer 50 along a thickness direction of the pixel definition layer 50 and exposes one first trace part 112. Two adjacent first contact holes 502 are respectively located at two opposite sides of one pixel aperture 501 in the first direction X and are spaced apart from the pixel aperture 501. The cathode layer 120 further covers hole walls of the multiple first contact holes 502, is in contact with the multiple first trace parts 112, and is electrically connected to the multiple first trace parts 112.

In the display panel 100 of the embodiment, the anode layer 40 is used to form the first trace part 112, and the signal transmitting layer 70 does not need to be additionally disposed to form the first trace part 112, which not only saves the manufacturing costs of the display panel 100, but also reduces the thickness of the display panel 100, thereby facilitating a light-weighted and thin design of the display panel 100.

Please refer to FIG. 1 and FIG. 4, where FIG. 4 is a schematic cross-sectional structural diagram of the display panel 100 illustrated in FIG. 1 taken along line I-I in the third embodiment.

The difference between the display panel 100 of the present embodiment and the display panel 100 of the first embodiment lies in that, the cathode signal trace 110 further includes multiple third trace parts 113, and the multiple third trace parts 113 are located in the display region 101. Specifically, the multiple third trace parts 113 are disposed on one side of the multiple first trace parts 112 away from the cathode layer 120 and respectively electrically connected to the multiple first trace parts 112. In the multiple third trace parts 113, part of the third trace parts 113 are arranged at intervals in the first direction X and each extend in the second direction Y, and part of the third trace parts 113 are arranged at intervals in the second direction Y and each extend in the first direction X.

The anode layer 40 includes the multiple third trace parts 113, and two adjacent third trace parts 113 are located at two opposite sides of one anode 41 in the first direction X and are spaced apart from the anode 41. A pixel definition layer 50 further defines multiple first contact holes 502, and each of the first contact holes 502 extends through the pixel definition layer 50 in a thickness direction of the pixel definition layer 50 and exposes one third trace part 113. Each first trace part 112 fills one first contact hole 502 and is electrically connected to one third trace part 113.

In the display panel 100 of the present embodiment, a signal transmitting layer 70 is used to jump to the anode layer 40 to realize a double-layer trace of the cathode signal trace 110 in the display region 101, which can reduce the thickness of the signal transmitting layer 70 to realize an effective transmission of an ELVSS signal, thereby not only saving the manufacturing cost of the display panel 100, but also reducing the thickness of the display panel 100 and facilitating the light-weight and thin design of the display panel 100.

Please refer to FIG. 5, which is a schematic cross-sectional structural diagram of the display panel 100 illustrated in FIG. 1 taken along line I-I in the fourth embodiment.

The difference between the display panel 100 of the present embodiment and the display panel 100 of the third embodiment lies in that, each first trace part 112 is spaced apart from one first contact hole 502 in the first direction X. The cathode layer 120 further covers hole walls of multiple first contact holes 502, is in contact with multiple third trace parts 113, and is electrically connected to the multiple third trace parts 113. In the display panel 100 of the present embodiment, the cathode layer 120 is used to jump to the anode layer 40 to realize a double-layer trace of the cathode signal trace 110 in the display region 101, which can reduce the impedance of the cathode layer 120, and reduce the power consumption of the display panel 100.

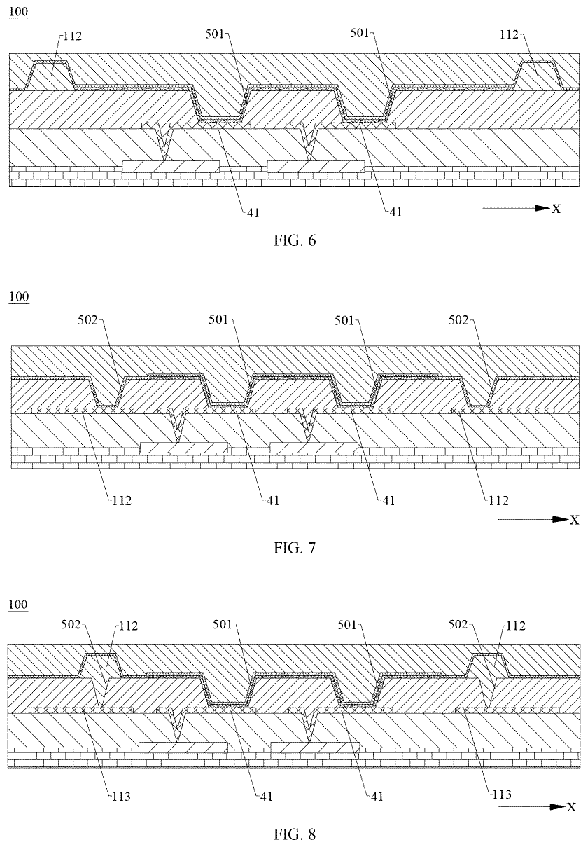

Please refer to FIG. 6, which is a schematic cross-sectional structural diagram of the display panel 100 illustrated in FIG. 1 taken along line I-I in the fifth embodiment.

The difference between the display panel 100 of the present embodiment and the display panel 100 of the first embodiment lies in that, two adjacent first trace parts 112 are respectively located at two opposite sides of two pixel apertures 501 in the first direction X. That is, two adjacent first trace parts 112 are respectively located at two opposite sides of two anodes 41 in the first direction X. In some other embodiments, two adjacent first trace parts 112 may also be respectively located at two opposite sides of three or more anodes 41 in the first direction X. In other words, in the embodiment, two adjacent first trace parts 112 may be located at two opposite sides of at least one anode 41 in the first direction X.

Please refer to FIG. 7, which is a schematic cross-sectional structural diagram of the display panel 100 illustrated in FIG. 1 taken along line I-I in the sixth embodiment.

The difference between the display panel 100 of the present embodiment and the display panel 100 of the second embodiment lies in that, two adjacent first trace parts 112 are respectively located at two opposite sides of two anodes 41 in the first direction X, and two adjacent first contact holes 502 are respectively located at two opposite sides of two pixel apertures 501. In some other embodiments, two adjacent first trace parts 112 may also be located at two opposite sides of three or more anodes 41 in the first direction X. In other words, in the present embodiment, two adjacent first trace parts 112 may be located at two opposite sides of at least one anode 41 in the first direction X.

Please refer to FIG. 8, which is a schematic cross-sectional structural diagram of the display panel 100 illustrated in FIG. 1 taken along line I-I in the seventh embodiment.

The difference between the display panel 100 of the present embodiment and the display panel 100 of the third embodiment in that, two adjacent third trace parts 113 are respectively located at two opposite sides of two anodes 41 in the first direction X, two adjacent first contact holes 502 are respectively located at two opposite sides of two pixel apertures 501, and two adjacent first trace parts 112 are respectively located at two opposite sides of two pixel apertures 501, namely, two adjacent first trace parts 112 are respectively located at two opposite sides of two anodes 41. In some other embodiments, two adjacent third trace parts 113 may also be located at two opposite sides of three or more anodes 41, and two adjacent first trace parts 112 may also be located at two opposite sides of three or more anodes 41. In other words, in the embodiment, two adjacent third trace parts 113 may be located at two opposite sides of at least one anode 41, and two adjacent first trace parts 112 may be located at two opposite sides of at least one anode 41.

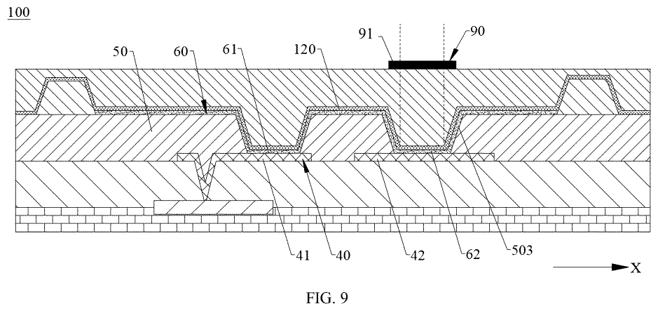

Please refer to FIG. 9, which is a schematic cross-sectional structural diagram of the display panel 100 illustrated in FIG. 1 taken along line I-I in the eighth embodiment.

The anode layer 40 further includes multiple privacy anodes 42, and each privacy anode 42 is located between two adjacent anodes 41 and is spaced apart from the two adjacent anodes 41. The pixel definition layer 50 further defines second contact holes 503, and the second contact holes each extend through the pixel definition layer 50 in the direction of the pixel definition layer 50 and each expose one privacy anode 42. The light emitting layer 60 further includes privacy pixels 62, and one privacy pixel 62 is located between two adjacent display pixels 61. Each of the privacy pixels 62 is disposed in one second contact hole 503 and is in contact with the privacy anode 42. The cathode layer 120 further covers the privacy pixels 62.

The display panel 100 further includes a light shielding layer 90. The light shielding layer 90 includes a light shielding unit 91. The light shielding unit 91 is arranged corresponding to the privacy anode 42 in a thickness direction of the display panel 100. The light shielding unit 91 may be a black matrix (BM). Specifically, a projection of the light shielding unit 91 on the anode layer 40 covers a projection of the privacy pixel 62 on the anode layer 40. When the display panel 100 operates, a light emitted by the privacy pixel 62 can be completely blocked by the light shielding unit 91 in a direction perpendicular to the display panel 100, thereby preventing the light emitted by the privacy pixel 62 from affecting normal display of the display panel 100 and improving user experience.

In addition, a projected area of the light shielding unit 91 on the anode layer 40 is larger than a projected area of the privacy pixel 62 on the anode layer 40, which can increase a normal display angle of the display panel 100. When a user's visual angle is not completely perpendicular to the display panel 100, as long as the user's visual angle is within the normal display angle of the display panel 100, the user can clearly see a display picture of the display panel 100. When the user's view angle is not within the normal display angle of the display panel 100, the user cannot see clearly the display picture of the display panel 100, so as to achieve a privacy protection.

In the embodiment, the cathode signal trace 110 forms a grid-like signal trace in the display region 101, and can provide a path for inputting an ELVSS signal to the cathode layer 120 from the whole display region 101. A contact region electrically connected to the cathode layer 120 does not need to be disposed in the non-display region 102, and the width of the non-display region 102 can be reduced, which helps to reduce the frame of the display panel 100 and improve the screen-to-body ratio. Furthermore, since the ELVSS signal is input into the cathode layer 120 from the whole display region 101, and the cathode layer 120 does not need to be used to transmit the ELVSS signal from an edge of the display region 101 to a middle of the display region 101, the trace voltage drop of the ELVSS signal is reduced, which helps to improve the display uniformity of the display region 101, and the trace resistance of the cathode layer 120 and the power consumption of the display panel 100 are also reduced.

Embodiments of the disclosure further provide a display terminal. The display terminal includes a housing and the above described display panel 100. The display panel 100 is mounted on the housing. The display terminal may be an electronic product such as a mobile phone, a tablet computer, and a notebook computer.

The above descriptions are merely detailed descriptions of the disclosure, but are not intended to limit the scope of protection of the disclosure. Any variation or replacement readily figured out by a person skilled in the art within the technical scope disclosed in the disclosure shall belong to the scope of protection of the disclosure. Without conflict, the embodiments of the disclosure and the features in the embodiments can be combined with each other. Therefore, the scope of protection of the disclosure shall be subject to the scope of protection of the claims.

What is claimed is:

1. A display panel having a display region and a non-display region surrounding the display region, wherein the display panel comprises a cathode signal trace and a cathode layer, the cathode signal trace comprises a first trace part, and the first trace part is located in the display region; and
the cathode layer is located at one side of the cathode signal trace, covers the display region, and is electrically connected to the first trace part.

2. The display panel of claim 1, wherein the first trace part is implemented as a plurality of first trace parts, part of the plurality of first trace parts are arranged at intervals in a first direction, part of the plurality of first trace parts are arranged at intervals in a second direction, and the second direction is different from the first direction.

3. The display panel of claim 1, wherein the cathode signal trace further comprises a second trace part, and the second trace part is located in the non-display region, surrounds the display region, and is electrically connected to both the first trace part and the cathode layer.

4. The display panel of claim 2, further comprising:
an anode layer, a pixel definition layer, a light emitting layer, and a signal transmitting layer, wherein the anode layer, the pixel definition layer, the light emitting layer, and the signal transmitting layer are all located at a same side of the cathode layer; the anode layer comprises a plurality of anodes, the pixel definition layer is disposed on one side of the anode layer facing towards the cathode layer, the pixel definition layer defines a plurality of pixel apertures, and each of the plurality of pixel apertures extends through the pixel definition layer in a thickness direction of the pixel definition layer and exposes one of the plurality of anodes; the light emitting layer comprises a plurality of display pixels, and each of the plurality of display pixels is disposed in one of the plurality of pixel apertures; and the signal transmitting layer is disposed on a surface of the pixel definition layer away from the anode layer, the signal transmitting layer comprises the plurality of first trace parts, two adjacent first trace parts are respectively located at two opposite sides of at least one anode, and the cathode layer covers the pixel definition layer, the light emitting layer, and the signal transmitting layer.

5. The display panel of claim 4, wherein the cathode signal trace further comprises a plurality of third trace parts, the plurality of third trace parts are all located in the display region, part of the plurality of third trace parts are arranged at intervals in the first direction, and part of the plurality of third trace parts are arranged at intervals in the second direction;
the anode layer further comprises the plurality of third trace parts, and two adjacent third trace parts are respectively located at two opposite sides of at least one anode and are spaced apart from the at least one anode;
the pixel definition layer further defines a plurality of first contact holes, each of the plurality of first contact holes extends through the pixel definition layer in a thickness direction of the pixel definition layer and exposes one of the plurality of third trace part, and two adjacent first contact holes are respectively located at two opposite sides of at least one pixel aperture and are both spaced apart from the at least one pixel aperture; and
each of the plurality of first trace parts is disposed in one contact hole and is electrically connected to one third trace part.

6. The display panel of claim 4, wherein the cathode signal trace further comprises a plurality of third trace parts, the plurality of third trace parts are located in the display region, part of the third trace parts are arranged at intervals in the first direction, and part of the third trace parts are arranged at intervals in the second direction;
the anode layer further comprises the plurality of third trace parts, and two adjacent third trace parts are respectively located at two opposite sides of at least one anode and are spaced apart from the at least one anode;
the pixel definition layer defines a plurality of first contact holes, each of the plurality of first contact holes extends through the pixel definition layer in a thickness direction of the pixel definition layer and exposes one of the plurality of third trace parts, and two adjacent first contact holes are respectively located at two opposite sides of at least one pixel aperture and are both spaced apart from the at least one pixel aperture; and
the cathode layer is further disposed on hole walls of the plurality of first contact holes, and is electrically connected with the plurality of third trace parts.

7. The display panel of claim 4, wherein two adjacent first trace parts are located at two opposite sides of at least two anodes.

8. The display panel of claim 4, wherein the anode layer further comprises a privacy anode, the privacy anode is located between two adjacent anodes and is spaced apart from the two adjacent anodes;
the pixel definition layer defines a second contact hole, the second contact hole extends through the pixel definition layer in the thickness direction of the pixel definition layer and exposes the privacy anode;
the light emitting layer further comprises a privacy pixel, and the privacy pixel is disposed in the second contact hole; and
the display panel further comprises a light shielding layer, the light shielding layer comprises a light shielding unit, and a projection of the light shielding unit on the anode layer covers a projection of the privacy pixel on the anode layer.

9. The display panel of claim 2, further comprising:
an anode layer, a pixel definition layer, and a light emitting layer, wherein the anode layer, the pixel definition layer, and the light emitting layer are all located at a same side of the cathode layer; wherein
the anode layer comprises a plurality of anodes and the plurality of first trace parts, two adjacent first trace parts are located at two opposite sides of at least one anode and are spaced apart from the at least one anode, the pixel definition layer is disposed on one side of the anode layer facing the cathode layer, the pixel definition layer defines a plurality of pixel apertures and a plurality of first contact holes, the plurality of pixel apertures and the plurality of contact holes each extend through the pixel definition layer in a thickness direction of the pixel definition layer, each of the plurality of pixel apertures exposes one anode, each of the plurality of first contact holes exposes one first trace part, and two adjacent first contact holes are respectively located at two opposite sides of at least one pixel aperture and are spaced apart from the at least one pixel aperture; and
the light emitting layer comprises a plurality of display pixels, each of the plurality of display pixels is disposed in one pixel aperture, the cathode layer covers the pixel definition layer, a surface of the light emitting layer facing away from the anode layer, and hole walls of the plurality of first contact holes.

10. The display panel of claim 9, wherein two adjacent first trace parts are located at two opposite sides of at least two anodes.

11. The display panel of claim 9, wherein the anode layer further comprises a privacy anode, the privacy anode is located between two adjacent anodes and is spaced apart from the two adjacent anodes;
the pixel definition layer defines a second contact hole, the second contact hole extends through the pixel definition layer in the thickness direction of the pixel definition layer and exposes the privacy anode;
the light emitting layer further comprises a privacy pixel, and the privacy pixel is disposed in the second contact hole; and
the display panel further comprises a light shielding layer, the light shielding layer comprises a light shielding unit, and a projection of the light shielding unit on the anode layer covers a projection of the privacy pixel on the anode layer.

12. A display terminal, comprising:
a housing; and
a display panel mounted on the housing; wherein
the display panel has a display region and a non-display region surrounding the display region, the display panel comprises a cathode signal trace and a cathode layer, the cathode signal trace comprises a first trace part, and the first trace part is located in the display region; and
the cathode layer is located at one side of the cathode signal trace, covers the display region, and is electrically connected to the first trace part.

13. The display terminal of claim 12, wherein the first trace part is implemented as a plurality of first trace parts, part of the plurality of first trace parts are arranged at intervals in a first direction, part of the plurality of first trace parts are arranged at intervals in a second direction, and the second direction is different from the first direction.

14. The display terminal of claim 12, wherein the cathode signal trace further comprises a second trace part, and the second trace part is located in the non-display region, surrounds the display region, and is electrically connected to both the first trace part and the cathode layer.

15. The display terminal of claim 13, wherein the display panel further comprises:
an anode layer, a pixel definition layer, a light emitting layer, and a signal transmitting layer, wherein the anode layer, the pixel definition layer, the light emitting layer, and the signal transmitting layer are all located at a same side of the cathode layer; the anode layer comprises a plurality of anodes, the pixel definition layer is disposed on one side of the anode layer facing towards the cathode layer, the pixel definition layer defines a plurality of pixel apertures, and each of the plurality of pixel apertures extends through the pixel definition layer in a thickness direction of the pixel definition layer and exposes one of the plurality of anodes; the light emitting layer comprises a plurality of display pixels, and each of the plurality of display pixels is disposed in one of the plurality of pixel apertures; and the signal transmitting layer is disposed on a surface of the pixel definition layer away from the anode layer, the signal transmitting layer comprises the plurality of first trace parts, two adjacent first trace parts are respectively located at two opposite sides of at least one anode, and the cathode layer covers the pixel definition layer, the light emitting layer, and the signal transmitting layer.

16. The display terminal of claim 15, wherein the cathode signal trace further comprises a plurality of third trace parts, the plurality of third trace parts are all located in the display region, part of the plurality of third trace parts are arranged at intervals in the first direction, and part of the plurality of third trace parts are arranged at intervals in the second direction;
the anode layer further comprises the plurality of third trace parts, and two adjacent third trace parts are respectively located at two opposite sides of at least one anode and are spaced apart from the at least one anode;
the pixel definition layer further defines a plurality of first contact holes, each of the plurality of first contact holes extends through the pixel definition layer in a thickness direction of the pixel definition layer and exposes one of the plurality of third trace part, and two adjacent first contact holes are respectively located at two opposite sides of at least one pixel aperture and are both spaced apart from the at least one pixel aperture; and
each of the plurality of first trace parts is disposed in one contact hole and is electrically connected to one third trace part.

17. The display terminal of claim 15, wherein the cathode signal trace further comprises a plurality of third trace parts, the plurality of third trace parts are located in the display region, part of the third trace parts are arranged at intervals in the first direction, and part of the third trace parts are arranged at intervals in the second direction;
the anode layer further comprises the plurality of third trace parts, and two adjacent third trace parts are respectively located at two opposite sides of at least one anode and are spaced apart from the at least one anode;
the pixel definition layer defines a plurality of first contact holes, each of the plurality of first contact holes extends through the pixel definition layer in a thickness direction of the pixel definition layer and exposes one of the plurality of third trace parts, and two adjacent first contact holes are respectively located at two opposite sides of at least one pixel aperture and are both spaced apart from the at least one pixel aperture; and
the cathode layer is further disposed on hole walls of the plurality of first contact holes, and is electrically connected with the plurality of third trace parts.

18. The display terminal of claim 15, wherein two adjacent first trace parts are located at two opposite sides of at least two anodes.

19. The display terminal of claim 15, wherein the anode layer further comprises a privacy anode, the privacy anode is located between two adjacent anodes and is spaced apart from the two adjacent anodes;
the pixel definition layer defines a second contact hole, the second contact hole extends through the pixel definition layer in the thickness direction of the pixel definition layer and exposes the privacy anode;
the light emitting layer further comprises a privacy pixel, and the privacy pixel is disposed in the second contact hole; and
the display panel further comprises a light shielding layer, the light shielding layer comprises a light shielding unit, and a projection of the light shielding unit on the anode layer covers a projection of the privacy pixel on the anode layer.

20. The display terminal of claim 14, wherein the display panel further comprises:
an anode layer, a pixel definition layer, and a light emitting layer, wherein the anode layer, the pixel definition layer, and the light emitting layer are all located at a same side of the cathode layer; wherein
the anode layer comprises a plurality of anodes and the plurality of first trace parts, two adjacent first trace parts are located at two opposite sides of at least one anode and are spaced apart from the at least one anode, the pixel definition layer is disposed on one side of the anode layer facing the cathode layer, the pixel definition layer defines a plurality of pixel apertures and a plurality of first contact holes, the plurality of pixel apertures and the plurality of contact holes each extend through the pixel definition layer in a thickness direction of the pixel definition layer, each of the plurality of pixel apertures exposes one anode, each of the plurality of first contact holes exposes one first trace part, and two adjacent first contact holes are respectively located at two opposite sides of at least one pixel aperture and are spaced apart from the at least one pixel aperture; and
the light emitting layer comprises a plurality of display pixels, each of the plurality of display pixels is disposed in one pixel aperture, the cathode layer covers the pixel definition layer, a surface of the light emitting layer facing away from the anode layer, and hole walls of the plurality of first contact holes.
